(19) United States
(12) Patent Application Publication
(10) Pub. No.: US 2024/0153561 A1
(43) Pub. Date: May 9, 2024

(54) MEMORY DEVICE

(71) Applicant: Rohm Co., Ltd., Kyoto (JP)

(72) Inventor: Yuichi Kokusho, Kyoto (JP)

(21) Appl. No.: 18/412,040

(22) Filed: Jan. 12, 2024

Related U.S. Application Data
(63) Continuation of application No. PCT/JP2022/024887, filed on Jun. 22, 2022.

(30) Foreign Application Priority Data
Jul. 14, 2021 (JP) 2021-116060

(51) Int. Cl. G11C 16/10; G11C 16/24; G11C 16/34

(52) U.S. Cl. CPC G11C 16/102; G11C 16/24; G11C 16/3404

(57) ABSTRACT

A memory device includes: a memory cell that includes: a first region; and a second region in which writing can be performed only once; and a control unit. First region information on a region of the second region in which data to be written to a register is stored and second region information on a region of the register to which the data is written can be written to the first region. The control unit performs writing to the register from the second region based on the first region information and the second region information stored in the first region.

### CROSS-REFERENCE TO RELATED APPLICATIONS

This nonprovisional application is a continuation application of International Patent Application No. PCT/JP2022/024887 filed on Jun. 22, 2022, which claims priority Japanese Patent Application No. 2021-116060 filed on Jul. 14, 2021, the entire contents of which are hereby incorporated by reference.

### TECHNICAL FIELD

The invention disclosed in the present specification relates to memory devices.

### BACKGROUND ART

Conventionally, various types of memory devices such as an OTP (One Time Programmable ROM) are proposed (see Patent Document 1 for an example of the OTP). The OTP is a memory in which writing can be performed only once.

### RELATED ART DOCUMENT

### Patent Document

Patent Document 1: Japanese Unexamined Patent Application Publication No. 2020-154584

### BRIEF DESCRIPTION OF DRAWINGS

FIG. 1 is diagram showing the configuration of a power supply device according to an exemplary embodiment of the present disclosure;

FIG. 2 is a block diagram showing an example of the configuration of an OTP block;

FIG. 3 is a diagram showing a specific example of the configuration of a memory cell;

FIG. 4 is a flowchart for an example of writing processing to a register;

FIG. 5 is a diagram showing an example of writing to the register;

FIG. 6 is a diagram showing the example of the writing to the register;

FIG. 7 is a diagram showing the example of the writing to the register;

FIG. 8 is diagram showing the configuration of a power supply device according to another embodiment;

FIG. 9 is a diagram showing an example of the configuration of an overvoltage detection circuit and a undervoltage detection circuit

FIG. 10 is diagram showing an example of a first search;

FIG. 11 is diagram showing an example of a second search;

FIG. 12 is a diagram showing the configuration of a voltage regulation circuit in another embodiment;

FIG. 13 is a diagram showing an example of a configuration on stop control for other functional units; and

FIG. 14 is a timing chart showing an example of the stop control for other functional units.

### DESCRIPTION OF EMBODIMENTS

Exemplary embodiments of the present disclosure will be described below with reference to drawings.

<1. Target of Application of Memory Device>

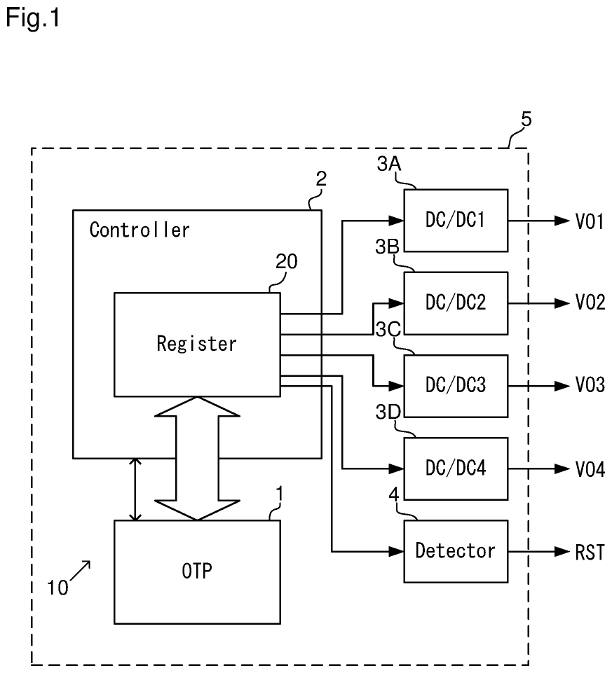

FIG. 1 shows the configuration of a power supply device 5 serving as an example of the target (application) to which a memory device according to an exemplary embodiment of the present disclosure is applied. The power supply device 5 includes the memory device 10.

The power supply device 5 is a semiconductor device (IC package) which includes an OTP block 1, a control unit (controller) 2, DC/DC converter circuits 3A to 3D and a detector 4 by integrating them into one chip. The power supply device 5 can generate a plurality of output voltages VO1 to VO4, and is installed in, for example, a vehicle.

The OTP block 1 includes a memory cell and its peripheral circuit (both of which are not shown). In the memory cell, various types of setting information and the like are stored. The detailed configuration of the OTP block 1 will be described later.

The control unit 2 is a device which controls the portions of the power supply device 5. The control unit 2 controls, for example, the OTP block 1. The memory device 10 includes the OTP block 1 and the control unit 2. In other words, the power supply device includes the memory device 10.

The control unit 2 includes a register 20. Data which is read from the OTP block 1 (memory cell) by an instruction of the control unit 2 is stored in the register 20.

The DC/DC converter circuits 3A to 3D subject input voltages to DC/DC conversion to convert the input voltages to the output voltages VO1 to VO4, and outputs the output voltages VO1 to VO4. The setting values of the output voltages VO1 to VO4 are set by data stored in the register 20.

The detector 4 detects, for example, an overvoltage or an undervoltage in each of the output voltages VO1 to VO4 to output a detection signal RST. The detection threshold value of the detector 4 is set by data stored in the register 20.

<2. Configuration of Memory Device>

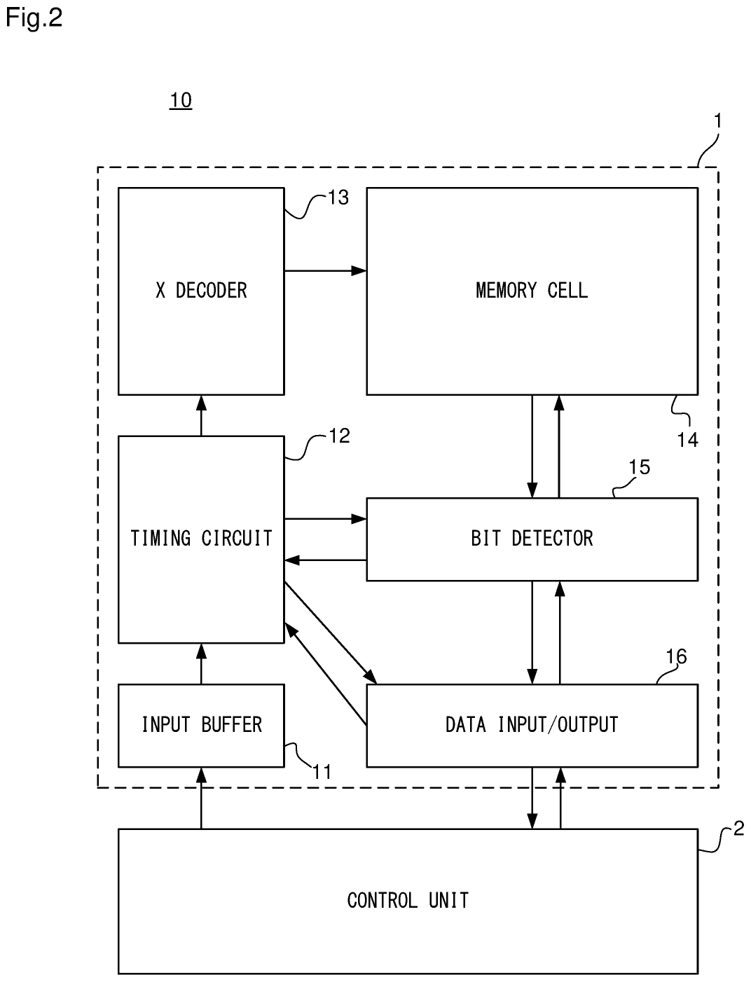

The configuration of the memory device 10 will then be described more specifically. FIG. 2 is a block diagram showing an example of the configuration of the OTP block 1.

As shown in FIG. 2, the OTP block 1 includes an input buffer 11, a timing circuit 12, an X decoder 13, the memory cell 14, a bit detector 15 and a data input/output unit 16.

The input buffer 11 stores addressing information which is input from the control unit 2. The timing circuit 12 performs timing control on the X decoder 13, the bit detector 15 and the data input/output unit 16.

The X decoder 13 selects a word line (row) in the memory cell 14 based on the addressing information input from the input buffer 11 via the timing circuit 12.

The memory cell 14 includes a plurality of cells which are arranged in a matrix. One cell includes transistors.

The bit detector 15 detects the logical value (0 or 1) of bit data stored in each of cells in the word line of the memory cell 14 selected by the X decoder 13. The data input/output unit 16 outputs, based on the result of the detection performed by the bit detector 15, the data in each of the cells in the selected word line to the control unit 2. In other words, the data in the selected word line is read by the bit detector 15 and the data input/output unit 16 from the memory cell 14.

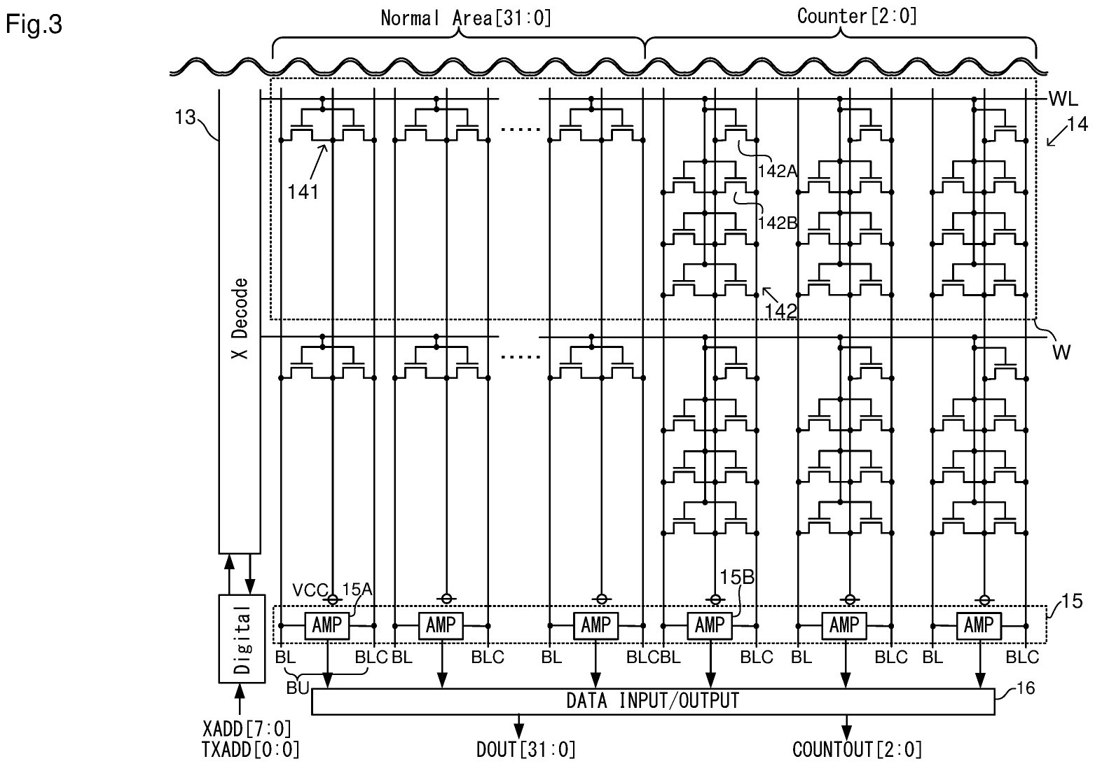

FIG. 3 is a diagram showing a specific example of the configuration of the memory cell 14. FIG. 3 shows only a part of the cells in the memory cell 14.

As shown in FIG. 3, the memory cell 14 includes a normal area and a counter area. In the normal area, OTP cells 141 are arranged in a matrix. In the counter area, counter cells 142 are arranged in a matrix.

The OTP cell 141 includes two MOS transistors. The gates of the two MOS transistors are commonly connected to the word line WL. The first ends of the two MOS transistors are connected together. The second end of one of the MOS transistors is connected to a bit line BL. The second end of the other MOS transistor is connected to a bit line BLC.

32 OTP cells 141 which have the connection configuration as described above are provided in each of the word lines WL. Hence, in the normal area, in each of the word lines WL, the data of 32 bits can be stored. The number of bits in the normal area is not limited to 32.

In the normal area, 32 bit line units BU each of which includes the bit line BL and the bit line BLC are provided. Between the bit lines BL and BLC in a bit line unit BU, a sense amplifier 15A is inserted. In other words, in the normal area, 32 sense amplifiers 15A are provided. The sense amplifiers 15A form the bit detector 15.

A voltage application unit VCC can apply a voltage to nodes to which the first ends of the MOS transistors in the OTP cells 141 connected between the bit lines BL and BLC in the bit line unit BU are connected.

In the OTP cell 141, charge is injected into the gate of one and the other MOS transistors, and thus data is written only once. According to which of the MOS transistors the charge is injected into, the value (0 or 1) of the bit data stored in the OTP cell 141 is different. The charge is injected into the gate of one of the MOS transistors in this way, and thus the threshold voltages of the MOS transistors in the OTP cell 141 are made different.

The X decoder 13 applies a predetermined voltage to the word line WL to select the word line WL. The voltage application unit VCC applies a voltage to the OTP cells 141 in the selected word line WL. In this state, by a difference in the threshold voltage between the MOS transistors in the OTP cell 141 of the selected word line WL, the levels of “on” of the MOS transistors are different. Hence, a different is caused between currents which flow through the MOS transistors. The sense amplifier 15A amplifies and outputs the difference between the currents. In this way, the sense amplifier 15A detects the logical value of the bit data stored in the OTP cell 141 of the selected word line WL.

The bit data in the 32 OTP cells 141 of the selected word line WL in the normal area is individually detected by 32 sense amplifier 15A. Then, the data input/output unit 16 outputs the normal area data DOUT of 32 bits based on the result of the detection performed by the sense amplifiers 15A.

The counter cell 142 includes a first cell 142A which includes one MOS transistor and a plurality of second cells 142B each of which includes two MOS transistors. The counter cell 142 includes 3 second cells 142B as an example.

The gate of the MOS transistor of the first cell 142A is connected to the word line WL. The first end of the MOS transistor is connected to the voltage application end of the voltage application unit VCC. The second end of the MOS transistor is connected to the bit line BLC.

The second cell 142B includes two MOS transistors. The gates of the two MOS transistors are commonly connected to the word line WL to which the gate of the first cell 142A is connected. In other words, the gates of a plurality of second cell 142B are connected to the common word line WL. The first ends of the two MOS transistors are connected together. The second end of one of the MOS transistors is connected to the bit line BL. The second end of the other MOS transistor is connected to the bit line BLC.

3 counter cells 142 which have the connection configuration as described above are provided in each of the word lines WL. Hence, in the counter area, the data of 3 bits can be stored in each of the word lines WL. In the normal area and the counter area, the word line WL is common. In other words, in one word line WL (one word region W in FIG. 3), 32 OTP cells 141 and 3 counter cells 142 are provided.

In the counter area, 3 bit line units BU each of which includes the bit line BL and the bit line BLC are provided. Between the bit lines BL and BLC in the bit line unit BU, a sense amplifier 15B is inserted. In other words, in the counter area, 3 sense amplifiers 15B are provided. The sense amplifiers 15B form the bit detector 15 together with the sense amplifiers 15A.

The voltage application unit VCC can apply a voltage to the first ends of the MOS transistors of the cells 142A and 142B in the counter cells 142 connected to the bit lines BL and BLC in the bit line unit BU.

When data is read from the counter cells 142, the X decoder 13 applies a predetermined voltage to the word line WL to select the word line WL. The voltage application unit VCC applies a voltage to the counter cells 142 (the first cells 142A and the second cells 142B) in the selected word line WL.

Here, when writing has not been performed yet to the counter cell 142, charge is not injected into the gates of the MOS transistors in the second cell 142B, and thus a difference in threshold voltage between the MOS transistors is not caused. On the other hand, by the configuration of the first cell 142A, a larger amount of current tends to flow to the side of the bit line BLC. Hence, for currents which flow from the counter cell 142 of the selected word line WL to the bit lines BL and BLC, a larger amount of current flows to the side of the bit line BLC. The sense amplifier 15B amplifiers and outputs a difference between the currents. If a state where a larger amount of current flows to the side of the bit line BLC is assumed to be “0” of bit data, the sense amplifier 15B detects, as “0”, the logical value of the bit data stored in the counter cell 142 of the selected word line WL.

On the other hand, when writing has been performed to the counter cell 142, charge is injected into the gates of the MOS transistors of a plurality of second cells 142B on the side of the bit line BLC, and thus the threshold voltage of the MOS transistors on the side of the bit line BLC is larger than the threshold voltage of the MOS transistors on the side of the bit line BL. Hence, for the currents which flow from the counter cell 142 of the selected word line WL to the bit lines BL and BLC, a larger amount of current flows to the side of the bit line BL. The sense amplifier 15B amplifiers and outputs a difference between the currents. When the bit data is defined as “0” as described above, the sense amplifier 15B detects, as “1”, the logical value of the bit data stored in the counter cell 142 of the selected word line WL.

By the configuration of the counter cell 142 as described above, in the state where writing has not been performed yet, writing is performed, and thus the bit data can be changed. Writing can be performed only once to the counter cell 142.

The bit data in the 3 counter cells 142 of the selected word line WL in the counter area is individually detected by the 3 sense amplifiers 15B. Then, the data input/output unit 16 outputs the counter area data COUNTOUT of 3 bits based on the result of the detection performed by the sense amplifiers 15B.

The control unit 2 determines, as bit data which is read, a larger number of pieces of bit data among the pieces of bit data in the counter area data COUNTOUT. In other words, the bit data which is read is determined by a majority vote. In this way, the bit data can be read from the counter area more reliably. The counter area data may be set to odd bits of 5 bits or more.

As described above, when the word line WL is selected by the X decoder 13, the data (32 bits+3 bits) is read from the cells in the normal area and the counter area of the selected word line WL and is output. However, 1 bit is substantially read from the counter area.

<3. Writing Processing to Register>

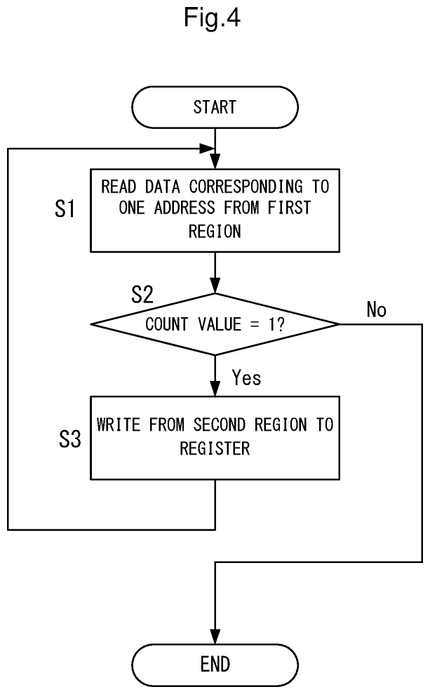

Writing processing from the memory cell 14 to the register 20 in the memory device 10 will then be described with reference to a flowchart shown in FIG. 4 and FIGS. 5 to 7.

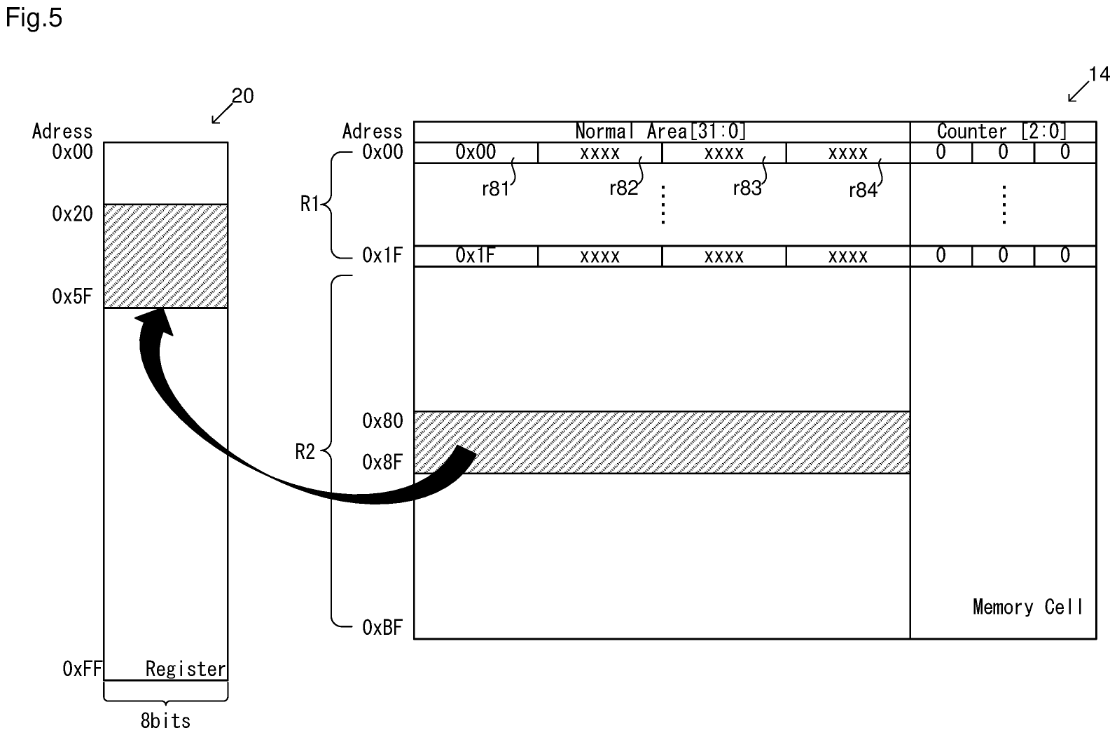

Here, as shown in FIGS. 5 to 7, the memory cell 14 includes a first region R1 and a second region R2. The address in the memory cell 14 shown in FIGS. 5 to 7 indicates one word.

In the first region R1, the first 8-bit region r81 from the highest order in the normal area (32 bits) indicates a self-address, the second 8-bit region r82 indicates the start address of a region to which writing is performed in the register 20 and the third and fourth 8-bit regions r83 and r84 respectively indicate the start address and the end address of a region in the normal area in which data to be written to the register 20 is stored. The number of bits in each of the areas r82, r83 and r84 is not limited to 8 bits. The first region R1 includes a counter area in addition to the normal area. When the data

in the start and end addresses has not been written to the normal area of the same addresses as the counter area, the state here is a state where writing has not been performed in the counter area. In this case, in the counter area, three pieces of bit data are set to “0”. For the writing to the first region R1, writing is performed only once in each address, and the writing is performed sequentially from the start address of the first region R1.

When the data in the start and end addresses is written to the normal area, writing is performed in the counter area, and the three pieces of bit data are set to “1”. The writing in the normal area and the counter area is performed by applying an overvoltage with an unillustrated circuit to one of a pair of MOS transistors in the memory cell and thereby injecting charge into the gate.

In the example shown in FIGS. 5 to 7, the first region R1 is a region from the first address (0x00) to 0x1F. However, the first region R1 is not limited to this configuration, and for example, the writing may be started from an address other the first address or the end address is not limited to 0x1F.

In the example shown in FIGS. 5 to 7, in the second region R2, the address subsequent to the end address (0x1F) of the first region R1 is set to the start address, and 0xBF is set to the end address. In the normal area of the second region R2, main data is stored. The main data includes various types of setting information and the like. The setting information includes setting output voltages of the DC/DC converter circuits 3A to 3D, the threshold voltage of the detector 4 and the like.

When the flowchart shown in FIG. 4 is started, the control unit 2 first specifies the address to read data corresponding to one address (corresponding to one word) from the first region R1 in the memory cell 14 (step S1). The data is first read from the start address in the first region R1.

Then, the control unit 2 determines whether the bit data (count value) read from the counter area is “1” (step S2). If the bit data is “1” (Yes in step S2), data is written to the 8-bit regions r82 and r83 in the normal area. Hence, the processing proceeds to step S3, and the control unit 2 writes data in a region included in the normal area of the second region from the start address written to the 8-bit region r83 to the end address written to the 8-bit region r84 to a region of the register 20 which starts from the start address written to the 8-bit region r82. The end address in the region of the register 20 to which the data is written is determined from the amount of data in the region from the start address to the end address in the second region R2.

Then, after step S3, the processing returns to step S1, and the control unit 2 performs reading from the address subsequent to the previous address in the first region R1.

When the count value read in step S2 is “0” (No in step S2), the flowchart shown in FIG. 4 is completed. In other words, data in a region other than the region to which the data has been written by the processing shown in FIG. 4 in the register 20 is used as the initial value without being processed.

An example of the processing shown in FIG. 4 as described above will be described with reference to FIGS. 5 to 7. In FIG. 5, in the first region R1 of the memory cell 14, writing has not been performed to the 8-bit regions r82 and r83 in all the addresses, and all pieces of bit data in the counter area are “0”.

When in the state of the memory cell 14 shown in FIG. 5, the processing shown in FIG. 4 is performed, reading is performed from the start address of the first region in step S1. Then, the count value read in step S2 is “0”, and thus the processing is completed.

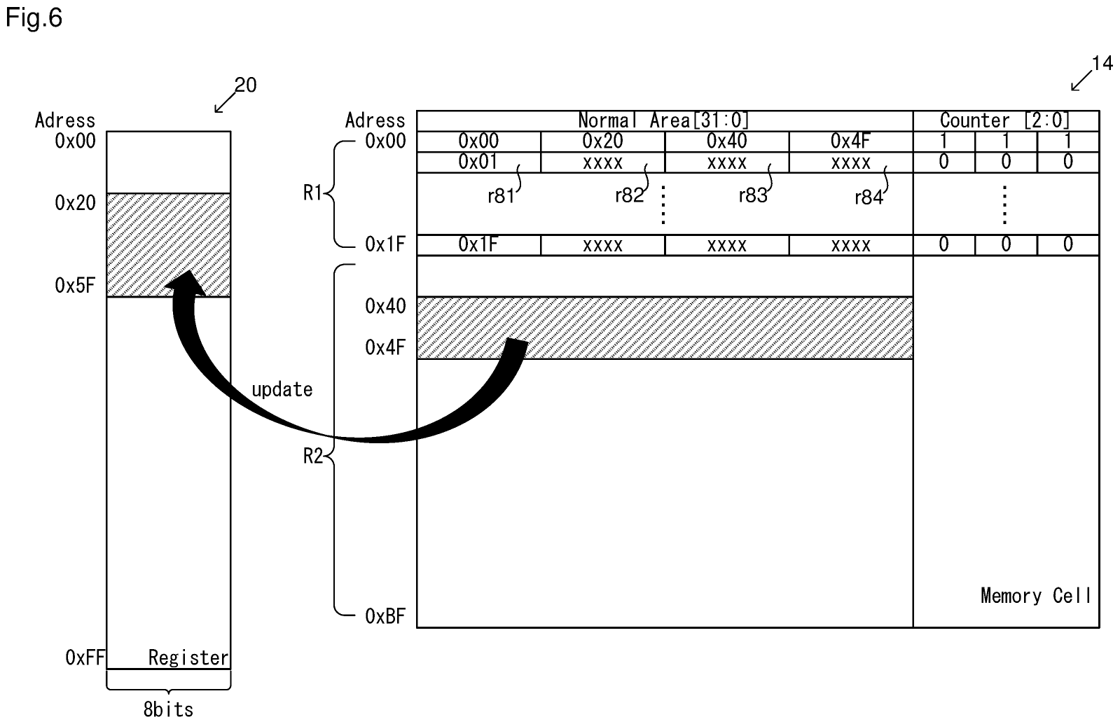

Then, in FIG. 6, in the state of the memory cell 14 shown in FIG. 5, address information (0x20, 0x40 and 0x4F) is written to the 8-bit regions r82 to r84 in the start address of the first region R1. In this way, in a state shown in FIG. 6, writing is performed in the counter area of the start address of the first region R1, and thus the three pieces of bit data are “1”.

When in the state shown in FIG. 6, the processing shown in FIG. 4 is performed, reading is performed from the start address of the first region in step S1. Then, since the read count value is “1” in step 2, the processing proceeds to step S3, and thus writing is performed from the region included in the normal area of the second region R2 from the start address 0x40 written to the 8-bit region r83 to the end address 0x4f written to the 8-bit region r84 to the region of the register 20 which starts from the start address 0x20 written to the 8-bit region r82.

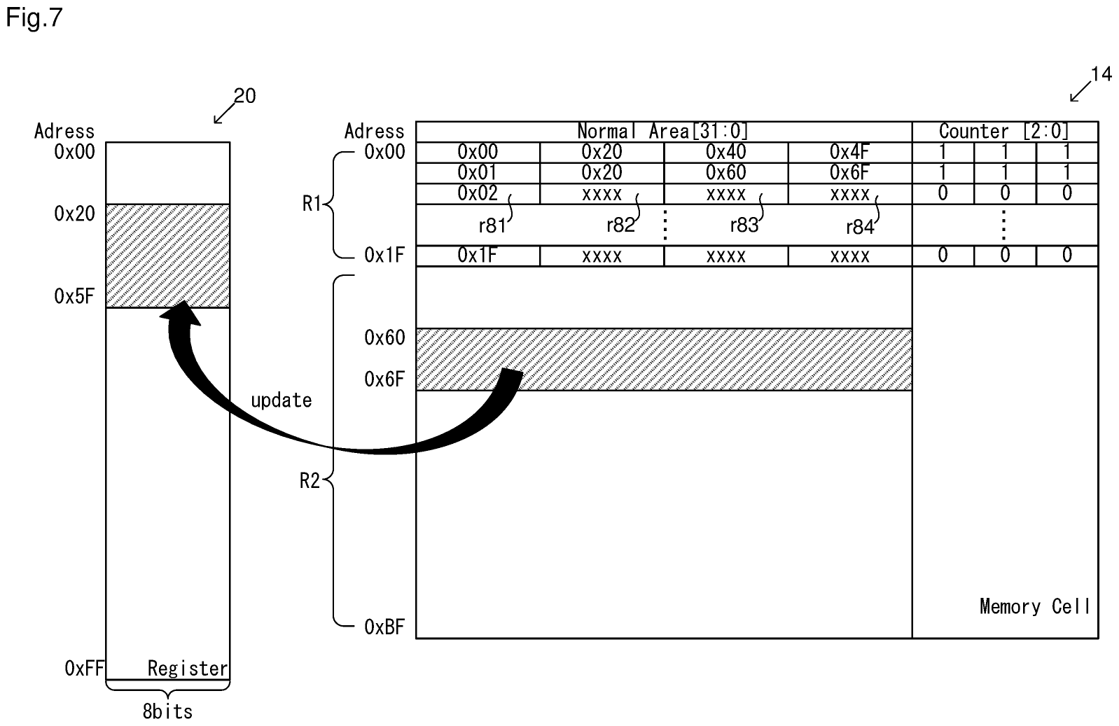

Then, in FIG. 7, in the state of the memory cell 14 shown in FIG. 6, address information (0x20, 0x60 and 0x6F) is written to the 8-bit regions r82 to r84 in the address subsequent to the start address of the first region R1. In this way, in a state shown in FIG. 7, writing is performed in the counter area of the address subsequent to the start address of the first region R1, and thus the three pieces of bit data are “1”.

When in the state shown in FIG. 7, the processing shown in FIG. 4 is performed, reading is performed from the start address of the first region in step S1. Then, since the read count value is “1” in step 2, the processing proceeds to step S3, and thus writing is performed from the region included in the normal area of the second region R2 from the start address 0x40 written to the 8-bit region r83 to the end address 0x4f written to the 8-bit region r84 to the region of the register 20 which starts from the start address 0x20 written to the 8-bit region r82.

Thereafter, the processing returns to step S1, and thus reading is performed from the address subsequent to the start address of the first region. Then, since the read count value is “1” in step 2, the processing proceeds to step S3, and thus writing is performed from the region included in the normal area of the second region R2 from the start address 0x60 written to the 8-bit region r83 to the end address 0x6f written to the 8-bit region r84 to the region of the register 20 which starts from the start address 0x20 written to the 8-bit region r82.

As described above, in the present embodiment, although in the normal area of the second region R2, writing can be performed to the OTP cells only once, writing is performed to the first region R1, and thus data which is written to the register 20 can be updated (FIGS. 6 and 7). Hence, writing can be performed to an OTP memory a plurality of times in a pseudo manner, and thus functions such as various types of settings can be flexibly changed.

<4. Power Supply Device in Another Embodiment>

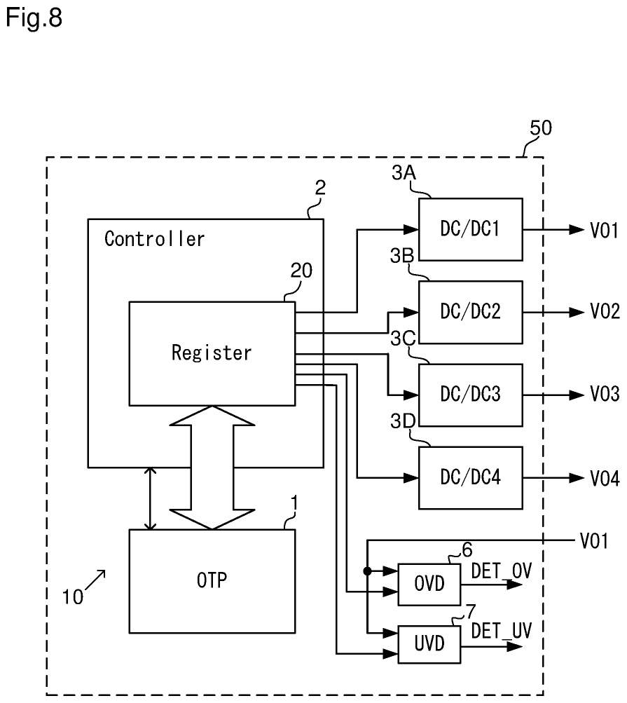

FIG. 8 is diagram showing the configuration of a power supply device 50 according to another embodiment. The power supply device 50 shown in FIG. 8 differs from the power supply device 5 (FIG. 1) according to the embodiment described previously in that the power supply device 50 includes an overvoltage detection circuit 6 and an undervoltage detection circuit 7.

When the overvoltage detection circuit (OVD) 6 compares the output voltage VO1 with the threshold voltage set by the control unit 2, and detects that the output voltage VO1 is increased to exceed the threshold voltage, the overvoltage detection circuit 6 outputs an overvoltage detection signal DT_OV indicating an overvoltage abnormality.

When the undervoltage detection circuit (UVD) 7 compares the output voltage VO1 with the threshold voltage set by the control unit 2, and detects that the output voltage VO1 is decreased to drop below the threshold voltage, the undervoltage detection circuit 7 outputs an undervoltage detection signal DT_UV indicating an undervoltage abnormality.

<5. Overvoltage Detection Circuit and Undervoltage Detection Circuit>

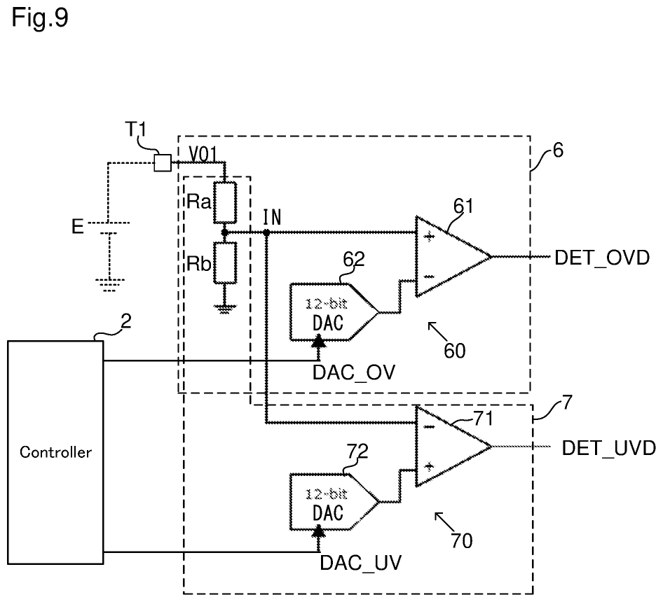

FIG. 9 is a diagram showing an example of the configuration of the overvoltage detection circuit 6 and the undervoltage detection circuit 7.

The overvoltage detection circuit 6 includes resistors Ra and Rb for voltage division, a comparator 61 and a digital analog converter (hereinafter referred to as a “DAC”) 62. One end of the resistor Ra is connected to an external terminal T1. The external terminal T1 is included in the power supply device 50 (FIG. 8), and can apply the output voltage VO1. The other end of the resistor Ra is connected to one end of the resistor Rb. The other end of the resistor Rb is connected to the application end of a ground. In other words, the resistors Ra and Rb are connected in series between the application end of the output voltage VO1 and the application end of the ground.

A node to which the resistors Ra and Rb are connected is connected to the non-inverting input terminal (+) of the comparator 61. In this way, an input voltage IN obtained by dividing the output voltage VO1 with the resistors Ra and Rb can be input to the non-inverting input terminal of the comparator 61. On the other hand, the DAC 62 subjects DAC data DT_DAT_OVD input from the control unit 2 to D/A conversion and inputs the resulting analog signal to the inverting input terminal (−) of the comparator 61.

In this way, the comparator 61 compares the input voltage IN with the analog signal serving as a reference voltage which is output from the DAC 62, and outputs an overvoltage detection signal DET_OVD as the result of the comparison. The comparator 61 may be a hysteresis comparator with hysteresis or may be a comparator without hysteresis.

When the output voltage VO1 is increased and thus the input voltage IN exceeds the reference voltage, the output voltage VO1 is assumed to exceed the threshold voltage, and thus the overvoltage detection signal DET_OVD output from the comparator 61 is switched from low to high.

The undervoltage detection circuit 7 includes the resistors Ra and Rb for voltage division, a comparator 71 and a DAC 72. The resistors Ra and Rb are shared with the overvoltage detection circuit 6.

The node to which the resistors Ra and Rb are connected is connected to the inverting input terminal (−) of the comparator 71. In this way, the input voltage IN obtained by dividing the output voltage VO1 with the resistors Ra and Rb can be input to the inverting input terminal of the comparator 71. On the other hand, the DAC 72 subjects DAC data DAC_UV input from the control unit 2 to D/A conversion and inputs the resulting analog signal to the non-inverting input terminal (+) of the comparator 71.

In this way, the comparator 71 compares the input voltage IN with the analog signal serving as a reference voltage which is output from the DAC 72, and outputs an undervoltage detection signal DET_UVD as the result of the comparison. The comparator 71 may be a hysteresis comparator with hysteresis or may be a comparator without hysteresis.

When the output voltage VO1 is decreased and thus the input voltage IN drops below the reference voltage, the output voltage VO1 is assumed to drop below the threshold voltage, and thus the undervoltage detection signal DET_UVD output from the comparator 71 is switched from low to high.

When the comparators 61 and 71 are formed with comparators with hysteresis, in a first search which will be described later, there is a restriction that it is impossible to make a search within a range including a hysteresis width and less. This is because, for example, when the output of the comparator is switched from low to high, it is impossible to accurately find a point at which the signal is switched from low to high unless the signal is returned from high to low.

<6. Voltage Regulation Circuit>

The comparator 61 and the DAC 62 included in the overvoltage detection circuit 6 and the control unit 2 constitute a voltage regulation circuit 60. The voltage regulation circuit 60 regulates the output (analog voltage) of the DAC 62 to a desired reference voltage. When the reference voltage in the overvoltage detection circuit 6 is regulated, as indicated by dashed lines in FIG. 9, in a state where a threshold voltage (predetermined voltage) for overvoltage detection is applied to the external terminal T1 externally by a voltage application unit E, DAC data DAC_OV in which the output of the DAC 62 matches the input voltage IN is searched for.

The comparator 71 and the DAC 72 included in the undervoltage detection circuit 7 and the control unit 2 constitute a voltage regulation circuit 70. The voltage regulation circuit 70 regulates the output (analog voltage) of the DAC 72 to a desired reference voltage. When the reference voltage in the undervoltage detection circuit 7 is regulated, as indicated by dashed lines in FIG. 9, in a state where a threshold voltage (predetermined voltage) for undervoltage detection is applied to the external terminal T1 externally by the voltage application unit E, DAC data DAC_UV in which the output of the DAC 72 matches the input voltage IN is searched for.

<7. Search Method>

The search described above is conducted by combining a first search and a second search. The first search is specifically a binary search. The second search is specifically a monotonous change (monotonous increase or monotonous decrease) search.

The first search (binary search) is a method in which while the input voltage IN and the outputs of the DACs 62 and 72 are being compared by the comparators 61 and 71, the bits of DAC data are determined sequentially from higher-order bits.

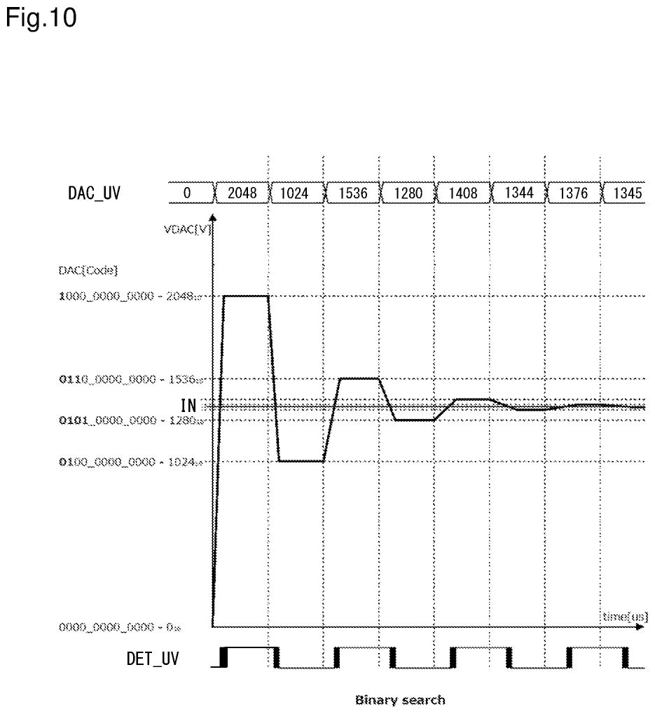

Here, an example of the first search conducted by the voltage regulation circuit 70 for the undervoltage detection circuit 7 will be described with reference to FIG. 10. Here, as an example, the DAC 72 is assumed to be the DAC of 12 bits.

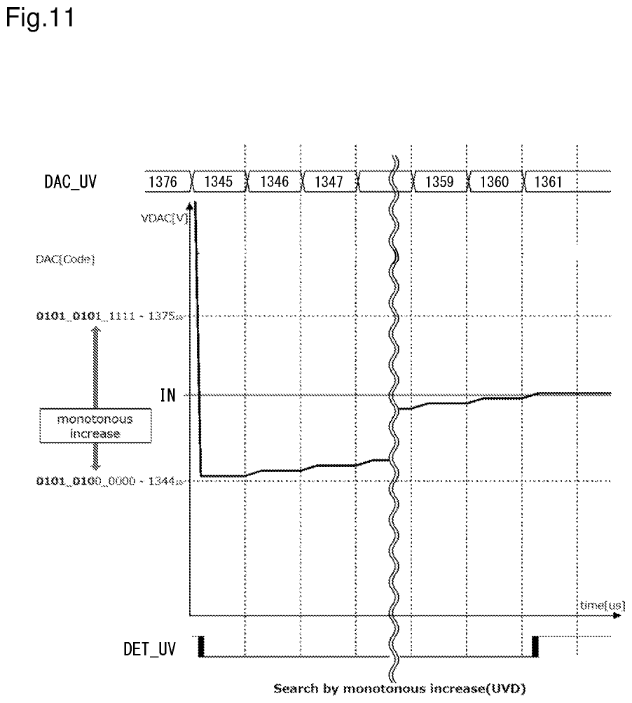

FIG. 10 shows the DAC data DAC_UV in the uppermost row which is chronologically set by the control unit 2, the code of the DAC data DAC_UV (binary and decimal notation) on the vertical axis of a graph, the waveform of the output (analog voltage) of the DAC 72 with respect to a time axis and the output of the comparator 71 in the lowermost row. FIG. 10 also shows the input voltage IN. The same is true in FIG. 11 which will be described later.

As shown in FIG. 10, the DAC data DAC_UV is initially set to 0x800, that is, a half value (=2048) in a 12-bit dynamic range. Here, the input voltage IN is lower than the output of the DAC 72, and thus the output of the comparator 71 is high.

By the output of the comparator 71, the control unit 2 determines that the most significant bit of the DAC data DAC_UV is “0”, then sets the subsequently highest-order bit (second highest-order bit) to “1” and sets the other bits to “0” (DAC data DAC_UV=0x400). In other words, the DAC data DAC_UV is set to the half value (=1024) of the lower half of the dynamic range described above. Here, the input voltage IN is higher than the output of the DAC 72, and thus the output of the comparator 71 is low.

By the output of the comparator 71, the control unit 2 determines that the second highest-order bit of the DAC data DAC_UV is “1”, then sets the subsequently highest-order bit (third highest-order bit) to “1” and sets the other bits to “0” (DAC data DAC_UV=0x600). In other words, the DAC data DAC_UV is set to the half value (=1536) of the upper half of a range divided in half by the half value set previously. Here, the input voltage IN is lower than the output of the DAC 72, and thus the output of the comparator 71 is high.

By the output of the comparator 71, the control unit 2 determines that the third highest-order bit of the DAC data DAC_UV is “0”, then sets the subsequently highest-order bit (fourth highest-order bit) to “1” and sets the other bits to “0”. Thereafter, processing is likewise repeated, and thus as shown in FIG. 10, and a determination is made up to the seventh highest-order bit, with the result that a setting is finally made such that DAC data DAC_UV=0x541.

The output of the DAC 72 here is lower than the input voltage IN, and thus the output of the comparator 71 is low. When the control unit 2 confirms from the output of the comparator 71 that the output of the DAC 72 is lower than the input voltage IN, the control unit 2 transfers to the second search.

The second search (monotonous change search) is a method in which the DAC data is increased or decreased by 1 in decimal form to monotonously increase or decrease the output of the DAC, and the DAC data when the output level of the comparator is switched is determined as the final DAC data.

After the first search in the example of FIG. 10 described previously, the second search shown in the example of FIG. 11 is conducted. In the example of FIG. 11, the search is started from the DAC data DAC_UV (=0x541) in which the output of the DAC 72 is lower than the input voltage IN, and thus the control unit 2 conducts the second search in monotonous increase. In this way, the DAC data DAC_UV is increased from 0x541 by 1 in decimal form, and the DAC data DAC_UV (=0x551) when the output level of the comparator 71 is switched from low to high is determined as the final DAC data. The reason why the second search in monotonous increase is conducted in the example

shown in FIG. 10 as described above is that in the undervoltage detection circuit 7, it is necessary to detect an undervoltage by detecting, with the comparator 71 with hysteresis, that the decreasing input voltage IN drops below the reference voltage output from the DAC 72 Likewise, since in the overvoltage detection circuit 6, it is necessary to detect an overvoltage by detecting, with the comparator 61 with hysteresis, that the increasing input voltage IN exceeds the reference voltage output from the DAC 62, the second search in monotonous decrease is conducted by the DAC 62. As described above, the control unit 2 switches the direction of monotonous change in the second search according to the function of an abnormal voltage detection circuit. When the comparator does not have hysteresis, the direction of monotonous change in the second search is not limited.

In the search method as described above, while the time necessary for the search is being reduced by the first search, a highly accurate search can be conducted by the second search. When the reference voltage which does not require high accuracy is regulated, the second search does not necessarily need to be conducted.

The regulation of the reference voltage as described above can be performed when the power supply device 50 is shipped from a factory or after the power supply device 50 is shipped from the factory. In particular, when the regulation is performed after the power supply device 50 is shipped from the factory, it is possible to handle chronological change. When the regulation is performed after the power supply device 50 is shipped from the factory, writing may be performed to the first region R1 (FIG. 5) in the memory cell 14 described previously according to the DAC data determined by the search.

<8. Voltage Regulation Circuit in Another Embodiment>

The voltage regulation circuit is not limited to abnormal voltage detection circuits such as the overvoltage detection circuit and the undervoltage detection circuit described previously, and the voltage regulation circuit can also be utilized for regulating the output voltage of the power supply device.

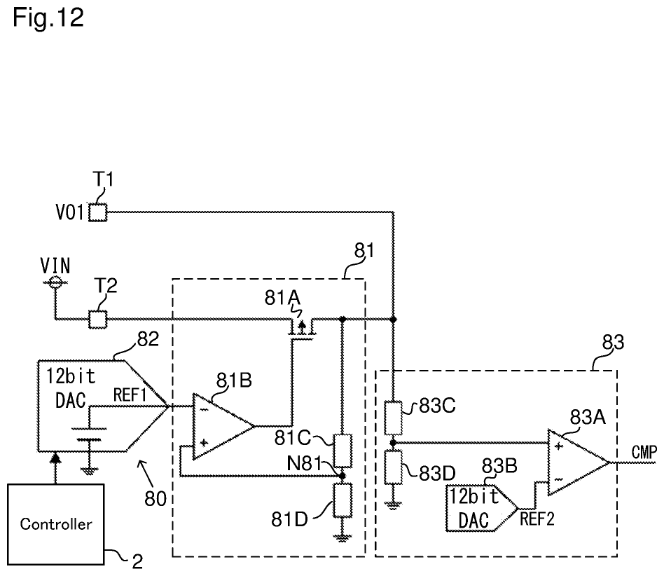

FIG. 12 is a diagram showing the configuration of a voltage regulation circuit 80 which is used for regulating the output voltage VO1 of a LDO (Low Dropout) 81 serving as an example of the power supply device.

The LDO 81 is a DC/DC converter circuit which converts an input voltage VIN to the output voltage VO1. The LDO 81 includes a PMOS transistor 81A, an error amplifier 81B and feedback resistors 81C and 81D. The source of the PMOS transistor 81A is connected to an external terminal T2. The input voltage VIN can be applied to the external terminal T2. The drain of the PMOS transistor 81A is connected to one end of the feedback resistor 81C. The other end of the feedback resistor 81C is connected to one end of the feedback resistor 81D. The other end of the feedback resistor 81D is connected to the application end of a ground. A node N81 to which the feedback resistors 81C and 81D are connected is connected to the non-inverting input terminal (+) of the error amplifier 81B.

The voltage regulation circuit 80 is a circuit which regulates a reference voltage input to the inverting input terminal (−) of the error amplifier 81B in order to regulate the output voltage VO1 of the LDO 81 to a desired voltage. The voltage regulation circuit 80 includes a DAC 82, a comparison circuit 83 and a control unit 2.

The DAC 82 subjects DAC data input from the control unit 2 to D/A conversion, and outputs, as a reference voltage REF1, the resulting analog signal to the inverting input terminal of the error amplifier 81B. The comparison circuit 83 includes a comparator 83A, a DAC 83B and voltage dividing resistors 83C and 83D. Between the output end of the LDO 81 (the application end of the output voltage VO1) and the application end of the ground, the voltage dividing resistors 83C and 83D are connected in series. A node to which the voltage dividing resistors 83C and 83D are connected is connected to the non-inverting input terminal (+) of the comparator 83A. A reference voltage REF2 output from the DAC 83B is input to the inverting input terminal (−) of the comparator 83A.

In the LDO 81, the voltage of the node N81 is controlled to match the reference voltage REF1, and the output voltage VO1 is generated. A voltage obtained by dividing the output voltage VO1 with the voltage dividing resistors 83C and 83D is compared with the reference voltage REF2 by the comparator 83A. The comparator 83A outputs a comparison signal CMP as the result of the comparison.

Here, the reference voltage REF2 is set to a desired voltage by the DAC 83B. The search method described previously can be applied to this setting. The control unit 2 conducts the first search and the second search described previously while monitoring the comparison signal CMP to determine the DAC data in which the voltage input to the non-inverting input terminal (+) of the comparator 83A matches the reference voltage REF2. In this way, the reference voltage REF1 is regulated such that the output voltage VO1 matches the desired voltage.

The regulation is not limited to the regulation of the reference voltage REF1 by the DAC, and the feedback resistors 81C and 81D may be regulated.

<9. Stop Control for Other Functional Units>

When the search described previously is conducted, for highly accurate regulation, it is effective to prevent functions unnecessary for the search from being conducted.

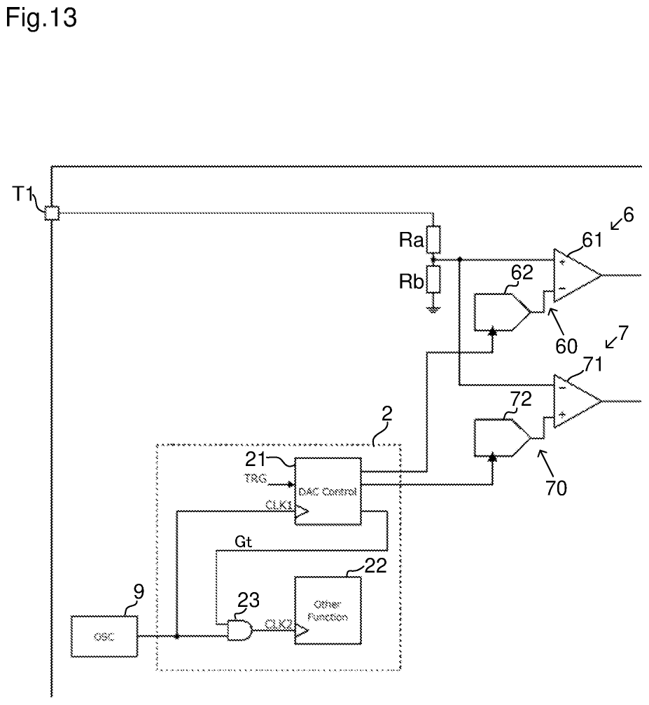

FIG. 13 is a diagram showing an example of a configuration on stop control for the other functional units. The configuration shown in FIG. 13 includes the configurations of the overvoltage detection circuit 6 and the undervoltage detection circuit 7 described previously. A control unit 2 shown in FIG. 13 includes a DAC control unit 21, other functional units 22 and an AND circuit 23.

DAC data is input from the DAC control unit 21 to the DACs 62 and 72 in the overvoltage detection circuit 6 and the undervoltage detection circuit 7. A clock signal CLK1 from an oscillator 9 is input to the DAC control unit 21. A gating signal Gt output from the DAC control unit 21 is input to the first input end of the AND circuit 23. The clock signal CLK1 is input to the second input end of the AND circuit 23. The output of the AND circuit 23 is input, as a clock signal CLK2, to the other functional units 22.

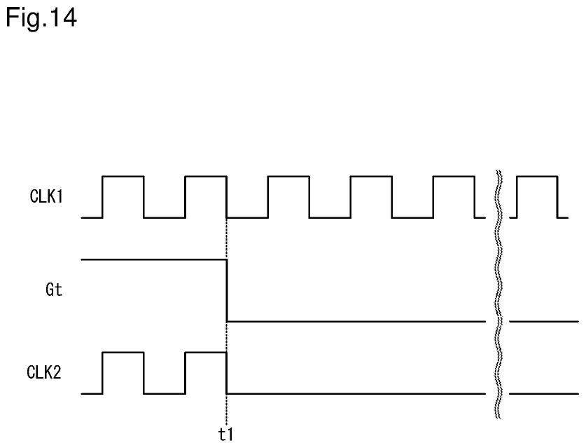

Here, the operation of the configuration shown in FIG. 13 will be described with reference to a timing chart shown in FIG. 14. FIG. 14 shows examples of the waveforms of the clock signal CLK1, the gating signal Gt and the clock signal CLK2.

When the DAC control unit 21 does not perform an operation (search) of regulating the reference voltage using the DACs 62 and 72, the gating signal Gt is high, and thus the AND circuit 23 outputs the clock signal CLK1 output from the oscillator 9 as the clock signal CLK2 without the clock signal CLK1 being processed (before timing 0). In this way, the other functional units 22 are operated.

Then, with the timing t1, a trigger signal TRG is input to the DAC control unit 21, and when the DAC control unit 21 starts the reference voltage regulating operation, the gating signal Gt is switched low. In this way, the clock signal CLK2 output from the AND circuit 23 is maintained low, and the supply of the clock signal CLK1 to the other functional units 22 is stopped. In this way, the operation of the other functional units 22 is stopped. When the search using the DACs 62 and 72 is completed, the gating signal Gt is switched high, and the supply of the clock signal CLK1 to the other functional units 22 is restarted.

<10. Summary>

A summary of the various embodiments described above will be given below.

For example, a memory device (10) disclosed in the present specification includes: a memory cell (14) that includes: a first region (R1); and a second region (R2) in which writing can be performed only once; and a control unit (2), first region information on a region of the second region in which data to be written to a register (20) is stored and second region information on a region of the register to which the data is written can be written to the first region and the control unit performs writing to the register from the second region based on the first region information and the second region information stored in the first region (first configuration).

In the first configuration described above, the first region information may be a start address and an end address in the second region, and the second region information may be a start address in the register (second configuration).

In the first or second configuration described above, in the first region, writing may be performed only once, and the first region may include a region (normal area) to which the first region information and the second region information are written and a region (counter area) to which information indicating whether or not the first region information and the second region information have been written is written (third configuration).

In the third configuration described above, the information indicating whether or not the first region information and the second region information have been written may be a count value represented by 1 bit (fourth configuration).

In the fourth configuration described above, as the information indicating whether or not the first region information and the second region information have been written, odd bit data of 3 or more may be written to the first region, and the control unit may determine the count value based on a majority vote of bit values of the odd bit data that are read (fifth configuration).

In any one of the third to fifth configurations, a cell (142) that stores bit data of the information indicating whether or not the first region information and the second region information have been written may include: one MOS transistor (142A) that is connected to one of two bit lines (BL and BLC); and a plurality of pairs (142B) each including two MOS transistors that are respectively connected to the one of two bit lines and the other thereof (sixth configuration).

A power supply device (5) disclosed in the present specification includes: the memory device of any one of the configurations described above (seventh configuration).

In the seventh configuration described above, the power supply device may include: a power supply circuit (3A), and the first region information may be information on a setting value of an output voltage of the power supply circuit (eighth configuration).

In the seventh or eighth configuration described above, the power supply device may include: a power supply circuit; and a detector (4) that detects an abnormality in an output voltage of the power supply circuit, and the first region information may be information on a setting value of a threshold voltage for detecting the abnormality with the detector (ninth configuration).

<11. Others>

Various changes can be added to various technical features disclosed in the present specification without departing from the spirit of the embodiments described above and the technical creation thereof. In other words, the embodiments described above should be considered to be illustrative in all respects and not restrictive, the technical range of the present invention is not limited to the embodiments described above and the technical scope of the present invention should be considered to include meanings equivalent to the scope of claims and all changes within the range.

### INDUSTRIAL APPLICABILITY

The present disclosure can be utilized for, for example, power supply devices.

### LIST OF REFERENCE SYMBOLS

1 OTP block
2 control unit
3A to 3D DC/DC converter circuit
4 detector
5 power supply device
6 overvoltage detection circuit
7 undervoltage detection circuit
9 oscillator
10 memory device
11 input buffer
12 timing circuit
13 X decoder
14 memory cell
15 bit detector
15A, 15B sense amplifier
16 data input/output unit
20 register
21 DAC control unit
22 other functional units
23 AND circuit
50 power supply device
60 voltage regulation circuit
61 comparator
70 voltage regulation circuit
71 comparator
80 voltage regulation circuit
81A PMOS transistor
81B error amplifier
81C, 81D feedback resistor
83 comparison circuit
83A comparator
83B DAC
83C, 83D voltage dividing resistor
141 OTP cell
142 counter cell
142A first cell
142B second cell
BL, BLC bit line
BU bit line unit
R1 first region
R2 second region
Ra, Rb resistor
T1, T2 external terminal
VCC voltage application unit
W one word region
WL word line
r81 to r84 8-bit region

1. A memory device comprising:
a memory cell that includes: a first region; and a second region in which writing can be performed only once; and
a control unit,
wherein first region information on a region of the second region in which data to be written to a register is stored and second region information on a region of the register to which the data is written can be written to the first region, and
the control unit performs writing to the register from the second region based on the first region information and the second region information stored in the first region.

2. The memory device according to claim 1,
wherein the first region information is a start address and an end address in the second region, and
the second region information is a start address in the register.

3. The memory device according to claim 1,
wherein in the first region, writing can be performed only once, and
the first region includes
a region to which the first region information and the second region information are written and
a region to which information indicating whether or not the first region information and the second region information have been written is written.

4. The memory device according to claim 3,
wherein the information indicating whether or not the first region information and the second region information have been written is a count value represented by 1 bit.

5. The memory device according to claim 4,
wherein as the information indicating whether or not the first region information and the second region information have been written, odd bit data of 3 or more is written to the first region, and
the control unit determines the count value based on a majority vote of bit values of the odd bit data that are read.

6. The memory device according to claim 3,
wherein a cell that stores bit data of the information indicating whether or not the first region information and the second region information have been written includes:
one MOS transistor that is connected to one of two bit lines; and
a plurality of pairs each including two MOS transistors that are respectively connected to the one of two bit lines and the other thereof.

7. A power supply device comprising:
the memory device according to claim 1.

8. The power supply device according to claim 7 comprising:
a power supply circuit,
wherein the first region information is information on a setting value of an output voltage of the power supply circuit.

9. The power supply device according to claim 7 comprising:
a power supply circuit; and
a detector that detects an abnormality in an output voltage of the power supply circuit,
wherein the first region information is information on a setting value of a threshold voltage for detecting the abnormality with the detector.
